(19) United States
(12) Patent Application Publication
(10) Pub. No.: US 2024/0415019 A1
(43) Pub. Date: Dec. 12, 2024

(54) HAPTIC DEVICE

(71) Applicant: TDK Electronics AG, Muenchen (DE)

(72) Inventors: Jockum Lönnberg, Deutschlandsberg (AT); Johannes Burger, Kirchlauter (DE); Wolfgang Wallnöfer, Deutschlandsberg (AT)

(21) Appl. No.: 18/712,244

(22) PCT Filed: Nov. 17, 2022
(86) PCT No.: PCT/EP2022/082295

§ 371 Date: May 21, 2024

(30) Foreign Application Priority Data
Nov. 24, 2021 (DE) 10 2021 130 788.0

(51) Int. Cl. H10N 30/20; H10N 30/80

(52) U.S. Cl. CPC H10N 30/20; H10N 30/80

(57) ABSTRACT

In an embodiment a haptic device includes a movable surface, an actuator configured to move the movable surface and a resilient abutment, wherein the actuator is arranged between the movable surface and the resilient abutment, and is configured such that when a force acts on the movable surface, a stiffness of the actuator has a first stiffness value below a first force value and a greater stiffness value above the first force value, and wherein a spring constant of the resilient abutment has a value, which lies between the first stiffness value and a second stiffness value.

### CROSS-REFERENCE TO RELATED APPLICATIONS

This patent application is a national phase filing under section 371 of PCT/EP2022/082295, filed Nov. 17, 2022, which claims the priority of German patent application 102021130788.0, filed Nov. 24, 2021, each of which is incorporated herein by reference in its entirety.

### TECHNICAL FIELD

The present invention relates to a haptic device for generating a haptic signal. Such a device has an actuator that generates a movement of a movable element. The movable element is configured, for example, as a touch-sensitive surface or a tip of a pen-like device. The actuator is, for example, a piezoelectric actuator or an electromagnetic actuator.

### BACKGROUND

The haptic device can be configured to generate a haptic signal, for example when touched. The haptic device can, for example, be configured as a touchscreen, trackpad, push button or stylus (pen-like device). In particular, the haptic device can be used in automobiles or computers.

DE 10 2015 117 262 A1 discloses a haptic device comprising a piezoelectric actuator. U.S. Pat. No. 8,416,066 B2 and WO 2020/011526 A1 both show a stylus.

With such devices, it is necessary on the one hand to design a flexible moving surface in order to enable effective movement by the actuator. On the other hand, actuators can be damaged by excessive external forces acting on the moving surface, e.g. in the event of a collision or fall.

To protect against excessive force, it is known to provide mechanical stop elements to limit the travel of haptic devices. For example, U.S. Pat. No. 9,379,305 B2 discloses a stop element on an enclosure plate, US 2012/0248935 A1 discloses a stop element on a base plate and US 2021/0280768 A1 discloses a thrust plate with travel limitation.

### SUMMARY

Embodiments provide a haptic device with improved properties. In particular, embodiments provide protection against overload is to be achieved while maintaining the haptic function.

According to a first embodiment of the present disclosure, a haptic device has a movable surface and an actuator for moving the movable surface. The haptic device is configured, for example, as a touch-sensitive screen or as a pen-shaped device (stylus). The haptic device can be configured to be held by a user, like a stylus, for example. With such a device, the risk of damage due to dropping the device is particularly high.

The movable surface is, in particular, an external surface that can be configured to output a haptic signal. The surface is, for example, the outer surface of a movable element such as the surface of a touchscreen or the tip of a stylus. The surface can also be directly a surface of the actuator. The actuator has, for example, a piezoelectric or electromagnetic transducer element that converts an electrical signal into a movement or deformation of the transducer element.

The actuator can alternatively or additionally be configured as a sensor, which is configured to detect an external force exerted on the moving surface. In particular, the actuator can be configured at the same time as an actuator and a sensor. The elements of the haptic device and the actuator can be present unchanged in a sensor function.

The actuator is arranged between the movable surface and a resilient abutment. The abutment is configured in particular to support the actuator and to generate a counterforce when the actuator expands. By suitably adjusting the stiffness behavior of the actuator and a spring constant of the abutment, it can be achieved that the actuator is better protected against overload. For this purpose, the actuator is configured in such a way that the stiffness of the actuator assumes different values depending on the value of an external force acting on the movable surface. In the case of a force whose value is below a first force value, the stiffness of the actuator has a first value. At a force whose value is above the force, the stiffness of the actuator has a second value that is greater than the first value. The spring constant of the abutment is between the first stiffness value and the second stiffness value.

For example, the spring constant D is at least 1.5 times greater than the first stiffness. For example, the spring constant is at least 100 N/mm greater than the first stiffness of the actuator. For example, the spring constant is at most 0.75 times greater than the second stiffness. For example, the spring constant is at least 100 N/mm less than the second stiffness of the actuator.

In this way, the actuator can be sufficiently compressible below the first force value to ensure haptic functionality. In particular, the operating range of the haptic device can lie below the first force value. The resilient abutment does not or only slightly impair the functionality in the operating range due to the greater spring constant. Above the first force value, the functionality of the abutment can then come into play, as the spring constant is smaller than the stiffness of the actuator. As a result, the abutment deforms more and the compression of the actuator decreases.

For example, the second stiffness value is at least twice as high as the first stiffness value. The second stiffness value can also be at least four times as high as the first stiffness value.

The abutment is connected to the edge of a housing of the haptic device, for example. The abutment can also be configured as an integral part of the housing. The abutment can only be held on one side, for example connected to the housing on one side. For example, the abutment is configured in the form of a bar. The abutment can also be held circumferentially or on two opposite sides. The abutment can also be of a different design, for example a plate that is resiliently mounted by a spring element.

The haptic device can comprise a travel limitation of the moving surface in the direction of the actuator, which is defined by a mechanical stop. For example, the stop is formed by the housing or a part fixed to the housing. The path limitation, i.e. a maximum path of the surface from a rest position in the direction of the actuator, can be greater than a compression of the actuator when the stop is reached. The compression of the actuator is hereby the change in thickness of the actuator in relation to a thickness of the actuator without the action of an external force.

For example, the compression of the actuator when the stop is reached is less than or equal to half of the travel limit. For example, the travel limit is at a value of 0.2 to 0.5 mm and the compression of the actuator is less than 0.15 mm.

The change in the stiffness of the actuator can be achieved, for example, by at least one support element that is supported on a transducer element of the actuator when the first force value is reached. For example, the support element is part of a reinforcing element that reinforces the movement of the actuator. The reinforcing element is in the form of a bracket, for example. The support element can be configured as a projection of the reinforcing element in the direction of the actuator. The support element can strike mechanically against the transducer when the first force value is reached. The support element can, for example, be an integral part of the reinforcing element or be attached to the reinforcing element. It is also possible to form the support element at the transducer element.

According to a further embodiment of the present disclosure, a method of manufacturing the haptic device described above is disclosed. In the method, an actuator with two preset stiffness values is provided. A resilient abutment is selected with a spring constant that lies between the stiffness values of the actuator.

In addition, a maximum compression of the actuator can be determined, i.e. a compression that is just still permissible so that the actuator is not damaged. A travel limit of the moving surface can be defined by a mechanical stop. The spring constant is then selected in such a way that, when the travel limit is reached, the compression of the actuator is less than the maximum compression of the actuator.

The present invention comprises several embodiments, in particular devices and methods. The features, properties and embodiments described for one of the embodiments shall also apply accordingly to the other embodiments.

### BRIEF DESCRIPTION OF THE DRAWINGS

Furthermore, the description of the objects specified here is not limited to the specific embodiments. Rather, the features of the individual embodiments can be combined with one another, where this makes technical sense.

FIG. 1 shows an embodiment of a haptic device in a cross-section;

FIG. 2 shows a displacement-force diagram of an embodiment of a haptic device; and

FIG. 3 shows a further embodiment of a haptic device in a cross-section.

Preferably, in the following figures, the same reference signs refer to functionally or structurally corresponding parts of the various embodiments.

### DETAILED DESCRIPTION OF ILLUSTRATIVE EMBODIMENTS

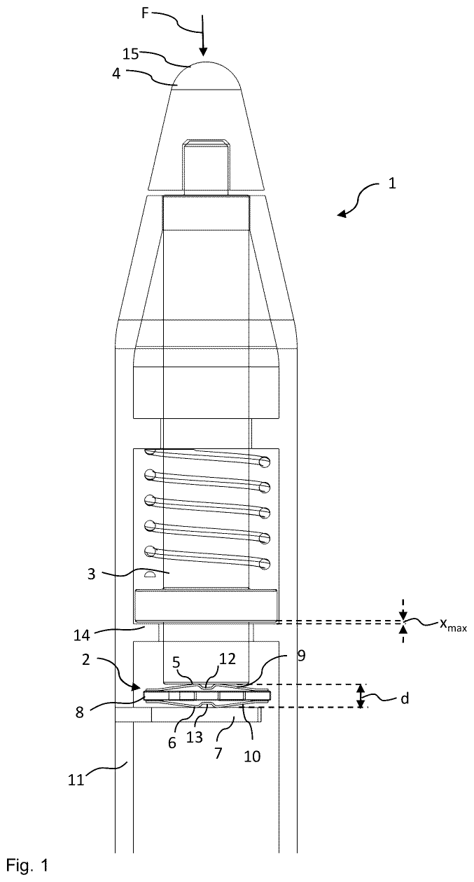

FIG. 1 shows a cross-section of an embodiment of a haptic device 1. The haptic device 1 is pen-shaped and is also referred to as a stylus. The haptic device 1 can be used as an input and/or output device, for example in a virtual reality application or an augmented reality application.

The haptic device 1 can create a specific haptic impression for a user. For example, the impression can be created that the haptic device 1 is being moved over a surface. Specific impressions of surface textures can also be created.

For this purpose, the haptic device 1 comprises an actuator 2 that is configured to generate movements that give the user a haptic impression. In particular, the actuator 2 is configured to generate vibrations.

The actuator 2 is configured to generate a movement of a movable surface 15. The movable surface 15 can be an outer surface of a movable element 3. In particular, the movable surface 15 is configured to be movable relative to a housing 11 of the haptic device 1. For example, the movable element 3 comprises a tip 4 of the haptic device 1. The movable element 3 can be formed in one or more parts. In some sections, the movable element 3 has the shape of a rod, in particular a shaft. The tip 4 can be an integral part of the rod-shaped area. The tip 4 can be moved over a surface and the movement of the tip 4 can create an impression of a surface texture for a user. It is also possible to arrange in a stylus a movable surface 15 and the movable element 3 such that the user comes into direct contact with the movable surface 15. In this case, for example, a movable surface 15 is arranged on the side of the haptic device 1 and the actuator 2 is accordingly oriented in a rotated manner.

The movement of the actuator 2 is transmitted to the movable element 3 via a first contact surface 5. A second contact surface 6 of the actuator 2 is in contact with a resilient abutment 7. When the actuator 2 expands, opposing forces are exerted on the contact surfaces 5, 6. The resilient abutment 7 can be permanently connected to the housing 11 or can also be an integral part of the housing 11.

The actuator 2 comprises a transducer element 8 that executes a movement, for example a deformation, expansion or contraction, when an electrical signal is applied. For example, the transducer element 8 is configured as a piezoelectric element. This may be a piezoceramic element. In particular, it can be a multilayer element. It is also possible to design the transducer element 8 in another way, for example as an electromagnetic actuator such as a voice coil (moving coil actuator).

The actuator 2 also comprises a reinforcing element 9 to amplify the magnitude of the movements, in particular the vibrations. The reinforcing element 9 is configured as a sheet metal, for example. The reinforcing element 9 is attached to the edge of the transducer element 3. In a central area, the reinforcing element 9 comprises the first contact surface 5, which is configured to act on the moving element 3. The central area of the reinforcing element 9 is at a distance from the transducer element 8 and can move relative to the transducer element 8. A movement of the transducer element 8 along an axial direction can be reinforced by the reinforcing element 9. The reinforcing element 9 is configured, for example, in the form of a bracket or a truncated cone.

On an opposite side of the transducer element 9, the actuator 2 has a further reinforcing element 10. The further reinforcing element 10 comprises the contact surface 6 to the abutment 7.

The distance between the contact surfaces 5, 6 defines a thickness d of the actuator 2. A compression Δd of the actuator 2 is a change in the thickness compared to the thickness without external force acting on the movable element 6, i.e. when the haptic device is at rest. When the actuator 2 vibrates during operation, the thickness is the average thickness of the actuator.

Excessive force F acting on the movable surface 15, for example when the haptic device 1 is hit or dropped, can damage the actuator 2. For example, the actuator 2 can hit the tip 4 if it is dropped. In particular, damage can occur if the compression Δd of the actuator 2 is too strong. For example, excessive compression Δd can lead to the reinforcing elements 9, 10 being damaged or the attachment to the transducer element 8 being impaired.

To limit the compression, the haptic device 1 can on the one hand have a mechanical stop 14 to limit the maximum travel of the movable surface 15 and the movable element 3 in the direction of the actuator 2. However, it has been found that it is often not technically feasible to use such a stop 14 to limit the travel so that it acts reliably before the actuator 2 is damaged and at the same time does not impair the haptic function. For example, it may be necessary for the stop 14 to allow a travel of the movable element 3 that is significantly greater than a maximum permissible compression Δdₘₐₓ of the actuator 2. For example, the maximum travel xₘₐₓ of the movable surface 15 and the movable element 3 is 0.3 mm, while the maximum permissible compression Δdₘₐₓ is 0.15 mm.

To limit the compression of the actuator 1, the abutment 7 is configured as a spring element. For example, the abutment 7 is configured as a leaf spring. The abutment 7 has the shape of a bar, for example. The abutment 7 is fixed to the edge of the housing 11. For example, the abutment 7 is only fixed to the housing 11 on one side. The abutment 7 can be an integral part of the housing 11. It is also possible for the abutment 7 to be fixed to the housing 11. For example, the abutment 7 is made of metal.

The abutment 7 has a spring constant D whose value is greater than the stiffness of the actuator 2 in an intended operating range. For example, the spring constant D is 300 N/mm.

For example, the actuator 2 has a stiffness S1 in the operating range. In particular, the stiffness of the actuator is a differential stiffness in the form of a derivative of the normal force on the contact surfaces 5, 6 according to the distance d between the contact surfaces 5, 6. The stiffness can have a constant value in certain distance ranges. It is also possible for the stiffness to change continuously.

The intended operating range is defined by a first value F1 of a force on the movable surface 15. As long as the force is less than or equal to the value F1, the haptic device is in the operating range in which haptic signals are to be output.

As the stiffness S1 of the actuator 2 is lower than the spring constant D of the abutment 7 in the operating range, the actuator 2 is predominantly compressed when a force is applied, while the abutment 7 is only slightly deformed. The fact that the spring constant D of the abutment 7 is greater than the stiffness S1 of the actuator 2 in the operating range means that the functionality of the actuator 2 is not or only slightly impaired. For example, the spring constant D is at least by 100 N/mm greater than the first stiffness S1 of the actuator 2. For example, the spring constant D is at least 1.5 times greater than the first stiffness S1.

The actuator 2 is configured in such a way that when the first force value F1 is exceeded, its stiffness has a value S2 that is greater than the spring constant of the abutment 7. In this way, the compression of the actuator 2 is reduced and a greater deformation of the abutment 7 is achieved.

To adjust the stiffness in different force ranges, the actuator 1 has one or more support elements 12, 13. For example, the support elements 12, 13 are arranged closer to the transducer element 8 than the respective contact surfaces 5, 6. The support elements 12, 13 can be integrated into the reinforcing elements 9, 10. For example, the support elements 12, 13 are formed as recesses in the reinforcing elements 9 and 10 and reduce the distance of the reinforcing elements 9 and 10 from the transducer element 8. For example, the distance is reduced in the vicinity of the contact surfaces 5, 6.

When an external force acts on the movable element 3 from a first value F1 and thus a certain compression of the actuator, the support elements 12, 13 come into contact with the transducer element 8. This leads to an increase in the stiffness of the actuator 1 from a first value S1 to a second value S2, making further compression of the actuator 1 more difficult.

The value S2 is greater than the spring constant D. For example, S2 is at least twice as large as S1. For example, S2>2×S1. S2 can be at least four times as large as S1. For example, S2>4×S1. In this way, it can be ensured that if the first force value F1 is exceeded, the further compression of the actuator 2 is significantly reduced.

When the movable element 3 comes into contact with the stop 14, a travel limit acts between the movable element 3 and the housing 11. For example, the stop 14 acts on the movable element 3 at a second force F2=50 N.

The stiffness S3 of the travel limit, which is essentially determined by the deformability of the movable element 3 and the stop 14, is greater than S2. For example, the stiffness S3 is at least twice as large as S2.

Overall, by using an abutment 7 and adjusting the stiffness values of the actuator 3, it can be achieved that the path of the moving surface 15 can be sufficiently large until the path limitation takes effect, so that the haptic functionality is not impaired, and at the same time effective protection of the actuator 2 against overload is achieved.

In a specific embodiment, the haptic device 1 is configured as a stylus, in particular as shown in FIG. 1. The actuator 2 is configured as a piezoelectric actuator. For example, the actuator has the dimensions 7×3.75×1.3 mm (length×width×height). The increase in the stiffness of the actuator 2 is achieved, for example, at a first force F1=5 N.

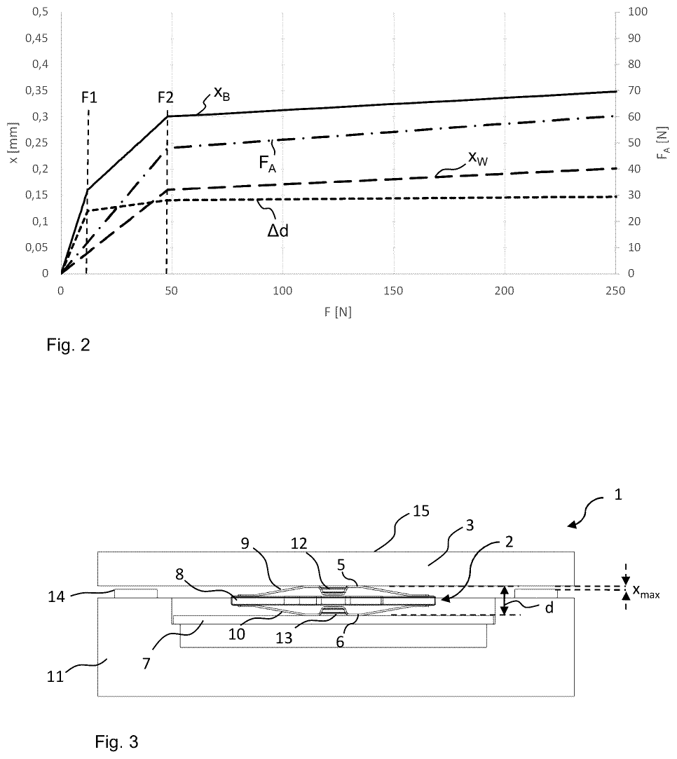

FIG. 2 shows a displacement-force diagram for the movement or compression of various components of the haptic device. The path x is given in mm and the force F from the outside on the movable element 6 or the tip 4 in N.

In the operating range, i.e. when a force F less than or equal to F1 is applied, the stiffness S1 of the actuator 2 is at a low value, so that the actuator 2 is highly compressed. The slope of the compression curve Δd is essentially determined by the stiffness S1.

When a force F of a value greater than or equal to F1 is applied, the rigidity of the actuator 2 increases. The increase in rigidity can be achieved by placing support elements 12, 13 against the transducer element 8. The increase in rigidity can also be achieved by other geometries of the reinforcing elements 9, 10. When a force greater than F1 is applied, the stiffness of the actuator 2 is greater than the spring constant of the abutment 7. The compression Δd of the actuator 2 only increases slightly t in this area as the force increases. Instead, the abutment 7 deforms more.

When the force value F2 is reached, the mechanical stop 14 acts on the moving element 3. The compression Δd of the actuator 2 only increases minimally when the force is increased. In particular, even with very high forces, the compression Δd remains below the maximum compression Δd of 0.15 mm, for example, even if the path of the moving part 3 to the stop is significantly greater, for example 0.3 mm or more.

Also shown in the diagram is the course of the deformation x_{W} of the abutment 7, in particular the movement of a central area of the abutment 7, against which the second contact surface 6 rests, in the direction of force F. In addition, the path x_{B} of the movable surface 15 or the movable element 3 in the direction of force F is shown. At a force greater than or equal to F2, the movable element 3 is in contact with the stop 14, so that a further displacement can only be achieved by deforming the components. For example, a curvature or deformation of the movable surface 15 or the movable element 3 or the stop 14 takes place here.

The force FA acting on the actuator 3 and the abutment 7 is also shown. Here, too, it can be seen how, due to the stop, the force FA increases only slightly from a value F2 of the externally acting force F.

The compression force on the actuator can be limited by the resilient abutment 7 and the setting of the stiffness values S1, S2 of the actuator 2. For example, the compression force on the actuator 2 remains below 80 N even if an external force of 400 N acts on the movable element 3.

FIG. 3 shows a further embodiment of a haptic device 1. Here too, an actuator 2 is arranged between a movable element 3 and a resilient abutment 7. The abutment 7 is held at the edge of a housing 11. For example, the abutment 7 is in the form of a bar or a disk. The actuator 2 can be configured as in the embodiment shown in FIG. 1. In particular, the actuator 2 is configured to increase its rigidity at a first force value F1. For this purpose, the actuator 2 comprises support elements 12, 13, which can be integrated into reinforcing elements 8, 9.

In contrast to the embodiment shown in FIG. 3, the haptic device 1 is not configured in the form of a stylus, but with a haptic touch surface, for example a touch screen or a push button. In particular, the movable element 3 has a movable surface 15 that is configured to be touched by a user with a finger or an input device to input a signal or receive feedback. For example, a user makes an input by pressing a finger or receives a haptic signal, in particular a haptic response to an input.

Here too, a mechanical stop 14 is used to limit the travel of the movable element 3. For example, the path limitation is at x_{B}=0.3 mm. The travel limit is reached, for example, at a force F2=50 N.

For example, the actuator 2 has component dimensions of 12×4×1.75 mm (length×width×height). The first stiffness S1 of the actuator is, for example, 100 N/mm. With a predetermined external force F of a first value F1, the stiffness of the actuator increases, for example, to a value S2=1800 N/mm. For example, the first value F1 is 8 N. The spring constant D of the abutment 7 lies between the stiffness values S1 and S2. For example, the spring constant D is 300 N/mm.

1.-15. (canceled)

16. A haptic device comprising:
a movable surface;
an actuator configured to move the movable surface; and
a resilient abutment,
wherein the actuator is arranged between the movable surface and the resilient abutment, and is configured such that when a force acts on the movable surface, a stiffness of the actuator has a first stiffness value below a first force value and a greater stiffness value above the first force value, and
wherein a spring constant of the resilient abutment has a value, which lies between the first stiffness value and a second stiffness value.

17. The haptic device according to claim 16, wherein the movable surface has a travel limit in a direction of the actuator, the travel limit being defined by a mechanical stop, and wherein a compression of the actuator is less than the travel limit when the mechanical stop is reached.

18. The haptic device according to claim 16, wherein the second stiffness value is at least twice as large as the first stiffness value.

19. The haptic device according to claim 16, wherein the spring constant is at least 1.5 times as large as the first stiffness value and at most 0.75 times as large as the second stiffness value.

20. The haptic device according to claim 16, wherein the actuator comprises a transducer element and at least one support element, which is supported on the transducer element when the first force value is reached.

21. The haptic device according to claim 20, wherein the actuator has at least one reinforcing element, which is configured to reinforce a movement of the actuator, the reinforcing element comprising the support element.

22. The haptic device according to claim 16, wherein the resilient abutment is connected to a housing of the haptic device or is an integral part of the housing.

23. The haptic device according to claim 16, wherein the resilient abutment is a bar and is mounted on one side.

24. The haptic device according to claim 16, wherein the haptic device is pen-shaped.

25. The haptic device according to claim 16, wherein the actuator is configured to act on a movable element, wherein the movable element is configured to be rod-shaped at least in some regions.

26. The haptic device according to claim 16, wherein the haptic device is configured to be held by a user.

27. The haptic device according to claim 16, wherein the actuator is further configured as a sensor.

28. The haptic device according to claim 16, wherein the movable surface is configured to be touched by a user.

29. A method for manufacturing the haptic device according to claim 16,
wherein the actuator has two preset stiffness values, and
wherein the resilient abutment has the spring constant selected such that the spring constant lies between the two stiffness values of the actuator.

30. The method according to claim 29,
wherein a maximum compression of the actuator is determined and a path limitation of the movable surface is defined by a mechanical stop, and
wherein the spring constant is selected such that the compression of the actuator, on reaching the stop, is less than the maximum compression of the actuator.
